(19) United States
(12) Patent Application Publication
(10) Pub. No.: US 2015/0093852 A1
(43) Pub. Date: Apr. 2, 2015

(54) METHOD FOR ENHANCING CONDUCTIVITY OF MOLYBDENUM THIN FILM BY USING ELECTRON BEAM IRRADIATION

(71) Applicants: Chae Hwan Jeong, Chungcheongnam-do (KR); Chae Woong Kim, Gwangju (KR); Dong Jin Kim, Gwangju (KR); Seung Chul Jung, Gwangju (KR)

(72) Inventors: Chae Hwan Jeong, Chungcheongnam-do (KR); Chae Woong Kim, Gwangju (KR); Dong Jin Kim, Gwangju (KR); Seung Chul Jung, Gwangju (KR)

(73) Assignee: KOREA INSTITUTE OF INDUSTRIAL TECHNOLOGY, Chungcheongnam-do (KR)

(21) Appl. No.: 14/358,702

(22) PCT Filed: Dec. 29, 2011
(86) PCT No.: PCT/KR2011/010278

§ 371 Date: May 15, 2014

(30) Foreign Application Priority Data
Dec. 15, 2011 (KR) 10-2011-0135838

(51) Int. Cl. H01L 31/0224

(52) U.S. Cl. CPC H01L 31/022441
USPC 438/98

(57) ABSTRACT

Disclosed is a method for manufacturing a solar cell, which is capable of enhancing the conductivity of a molybdenum thin film by decreasing the specific resistivity and thickness of the molybdenum thin film that is a back electrode. The method for manufacturing the solar cell according to the present invention includes: a step of forming a molybdenum thin film on a substrate; and a step of performing a post-processing process on the molybdenum thin film to form a back electrode. Here, the post-processing process with respect to the molybdenum thin film may be performed by irradiating an electron beam.

### TECHNICAL FIELD

The present invention relates to a method for manufacturing a solar cell, and more particularly, to a method for manufacturing a solar cell, being capable of enhancing conductivity of a molybdenum thin film by means of an electron beam irradiation.

### BACKGROUND ART

A solar cell is a device converting solar energy into electrical energy and may be broadly classified as a silicon-based solar cell, a compound-based solar cell, and an organic-based solar cell according to a material used therein.

The silicon-based solar cell is classified as a single crystal silicon solar cell, a polycrystalline silicon solar cell, and an amorphous silicon solar cell, and the compound-based solar cell is classified as a GaAs, InP, or CdTe solar cell, a CuInSe₂ (copper-indium-diselenide) or CuInS₂ (hereinafter, referred to as “CIS”) solar cell, a Cu(InGa)Se₂ (copper-indium-gallium-selenium) or Cu(InGa)S₂ (hereinafter, referred to as “CIGS”) solar cell, and a Cu₂ZnSnS₄ (copper-zinc-tin-sulfur; hereinafter, referred to as “CZTS”) solar cell.

In addition, the organic-based solar cell may be classified as an organic molecular solar cell, an organic-inorganic composite solar cell, and a dye-sensitized solar cell.

Among various solar cells described above, the single crystal silicon solar cell and the polycrystalline silicon solar cell include a light absorption layer on their substrates and thus, may be relatively unfavorable in terms of cost reduction.

Since the amorphous silicon solar cell includes a light absorption layer as a thin film, the amorphous silicon solar cell may be manufactured to have a thickness of about 1/100 of that of a crystalline silicon solar cell. However, the amorphous silicon solar cell may have efficiency lower than that of a single crystal silicon solar cell and the efficiency may rapidly decrease when exposed to light.

The organic-based solar cell has limitations, including very low efficiency and reduction in the efficiency due to oxidation when exposed to oxygen.

In order to compensate for such limitations, the compound-based solar cells have been developed. The compound-based solar cells, such as a CZTS solar cell, a CIS solar cell, and a CIGS solar cell, have the best conversion efficiency among thin-film type solar cells. However, such conversion efficiency is obtained in laboratories and thus, in order to commercialize the CZTS solar cell, the CIS solar cell, and the CIGS solar cell as a power application, many issues must be taken into consideration.

Meanwhile, in processes of manufacturing CIS and CIGS solar cells, a back electrode is formed by depositing molybdenum (Mo 110) on a glass substrate by DC sputtering.

In general, after forming the molybdenum electrode layer, a special post-processing process is not performed. In addition, a molybdenum thin film having specific resistance of approximately 3×10⁻⁵ and a thickness in a range of 400 nm to 1000 nm is used as a back electrode.

However, in the method for manufacturing a solar cell, lowering specific resistivity while decreasing a thickness of a molybdenum layer is considered as an important factor for achieving effects of saving materials and shortening a processing time.

### DISCLOSURE OF THE INVENTION

### Technical Problem

In order to overcome the above-mentioned shortcomings, the present invention provides a method for manufacturing a solar cell, which is capable of enhancing the conductivity of a molybdenum thin film by decreasing the specific resistivity and thickness of the molybdenum thin film that is a back electrode.

### Technical Solution

According to an aspect of the invention, there is provided a method for manufacturing a solar cell including forming a molybdenum thin film on a substrate; and performing a post-processing process on the molybdenum thin film to form a back electrode, wherein the post-processing process with respect to the molybdenum thin film is performed by irradiating an electron beam.

Here, the electron beam may be irradiated into the entire surface of the back electrode. In addition, the electron beam post-processing process may be performed in a processing chamber in an argon gas atmosphere of 7×10E⁻⁷ torr in pressure and 5 to 10 sccm in flow rate using the electron beam having DC power of 2.5 to 3.5 Kv and RF power of 200 to 300 W.

### Advantageous Effects

As described above, the method for manufacturing a solar cell according to the present invention can achieve effects of saving materials and shortening a processing time while decreasing the specific resistivity and thickness of a molybdenum thin film in the process of forming a back electrode.

### BRIEF DESCRIPTION OF THE DRAWINGS

FIG. 1 is a schematic view illustrating structures of a Cu—Zn—Sn—S (Cu₂ZnSnS₄) solar cell, a CuInS₂ solar cell, a Cu(InGa)Se₂ solar cell and a Cu(InGa)S₂ solar cell according to an embodiment of the present invention;

FIGS. 2A through 2G illustrate a process for manufacturing the solar cells shown in FIG. 1;

FIG. 3 illustrates photographs showing molybdenum thin films formed according to Comparative Example 1 and Example 1, in which the left photograph shows the molybdenum thin film formed according to Comparative Example 1 and the right photograph shows the molybdenum thin film formed according to Example 1, respectively;

FIG. 4 illustrates photographs showing molybdenum thin films formed according to Comparative Example 2 and Example 2, in which the left photograph shows the molybdenum thin film formed according to Comparative Example 2 and the right photograph shows the molybdenum thin film formed according to Example 2, respectively;

FIG. 5 illustrates photographs showing molybdenum thin films formed according to Comparative Example 3 and Example 3, in which the left photograph shows the molybdenum thin film formed according to Comparative Example 3 and the right photograph shows the molybdenum thin film formed according to Example 3, respectively;

FIG. 6 illustrates photographs showing molybdenum thin films formed according to Comparative Example 4 and Example 4, in which the left photograph shows the molybdenum thin film formed according to Comparative Example 4 and the right photograph shows the molybdenum thin film formed according to Example 4, respectively; and

FIG. 7 is a graph comparing resistivity measuring results of molybdenum thin films formed according to Comparative Examples 1 to 4 and Examples 1 to 4, in which the left graph shows resistivity measuring results of the molybdenum thin films formed according to Comparative Examples 1 to 4 and the right graph shows resistivity measuring results of the molybdenum thin films formed according to Examples 1 to 4.

### MODE FOR CARRYING OUT THE INVENTION

Hereinafter, a method of manufacturing a solar cell according to the present invention will be described in detail.

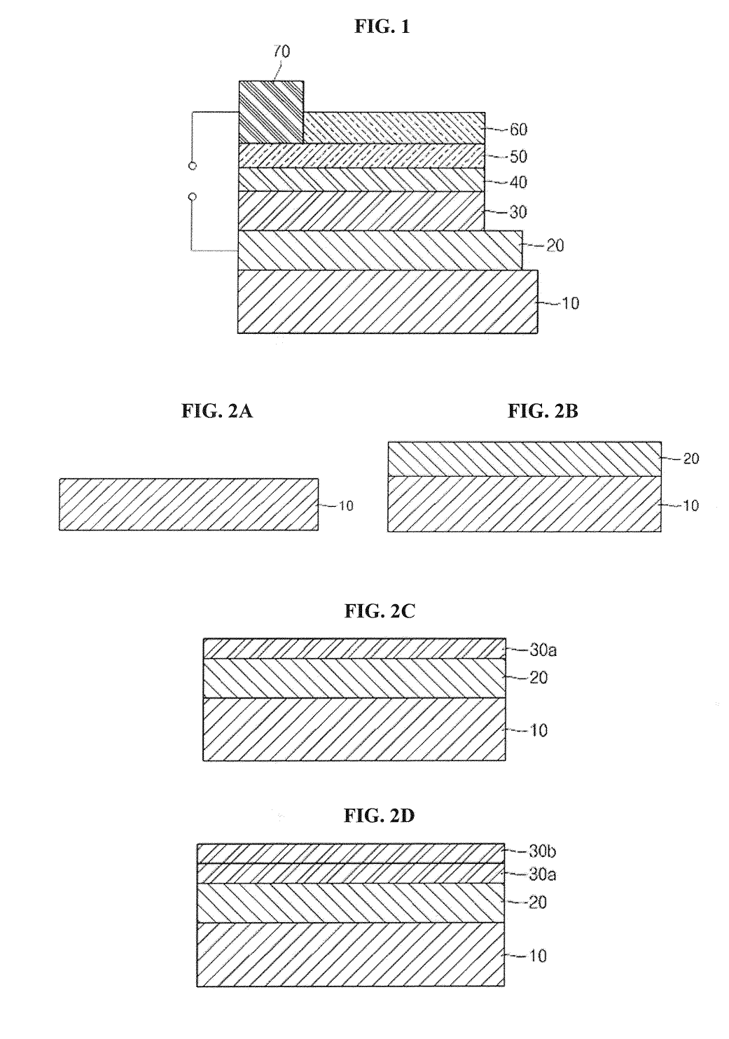

FIG. 1 is a schematic view illustrating structures of a Cu—Zn—Sn—S (Cu₂ZnSnS₄; referred to as “CZTS”) solar cell, a CuInSe₂ or CuInS₂ (hereinafter, referred to as “CIS”) solar cell, and a Cu(InGa)Se₂ or Cu(InGa)S₂ (hereinafter, referred to as “CIGS”).

The CZTS solar cell, the CIS solar cell, and the CIGS solar cell have the same structure. That is to say, each of the CZTS solar cell, the CIS solar cell, and the CIGS solar cell has a structure, in which a back electrode 20, a light absorption layer 30, a buffer layer 40, a window layer 50, and an anti-reflective layer 60 are sequentially formed on a substrate 10, and includes a grid electrode 70 formed in a patterned area of the anti-reflective layer 60.

Each component of the solar cell will be described in detail below.

Substrate 10

The substrate 10 may be formed of glass and may be manufactured by using ceramic, such as alumina as well as glass, a metallic material such as stainless steel and a cooper (Cu) tape, and a polymer.

Inexpensive soda-lime glass may be used as a material for the glass substrate. Also, a flexible polymer material, such as polyimide, or a stainless steel thin sheet may be used as a material for the substrate 10.

Back Electrode 20

Molybdenum (Mo) may be used as material for the back electrode 20 formed on the substrate 10.

Molybdenum has high electrical conductivity, forms an ohmic contact with a Cu—Zn—Sn—S (Cu₂ZnSnS₄) light absorption layer which is described later, and has high-temperature stability in a sulfur (S) atmosphere.

In addition, molybdenum forms an ohmic contact with CuInSe₂ light absorption layer or a CuInS₂ light absorption layer which is described later, and has high-temperature stability in a sulfur (S) atmosphere.

A molybdenum thin film as an electrode should have low specific resistance and excellent adhesion to the glass substrate so as not to cause a delamination phenomenon due to a difference in thermal expansion coefficients.

Light Absorption Layer 30

The light absorption layer 30 formed on the back electrode 20 is a p-type semiconductor actually absorbing light.

In a CZTS solar cell, the light absorption layer 30 is formed of Cu—Zn—Sn—S (e.g., Cu₂ZnSnS₄). Cu₂ZnSnS₄ has an energy bandgap of 1.0 eV or more and has the highest light absorption coefficient among semiconductors. Also, since Cu₂ZnSnS₄ is highly stable, a layer formed of such material may be considerably ideal as a light absorption layer of a solar cell.

Since a CZTS thin film as a light absorption layer is a multi-component compound, a manufacturing process is relatively complicated. A physical method of manufacturing the CZTS thin film includes evaporation and sputtering plus selenization, and a chemical method thereof includes electroplating. In each method, various manufacturing methods may be used according to types of a starting material (metal, binary compound, etc.).

Meanwhile, a CuInSe₂ layer or a CuInS₂ layer in a CIS solar cell and a Cu(InGa)Se₂ layer or a Cu(InGa)S₂ layer in a CIGS solar cell function as the light absorption layer 30. CuInSe₂, CuInS₂, Cu(InGa)Se₂ and Cu(InGa)S₂ have an energy bandgap of 1.0 eV or more and have the highest light absorption coefficient among semiconductors. In addition, since CuInSe₂, CuInS₂, Cu(InGa)Se₂, and Cu(InGa)S₂ are highly stable, a layer formed of such materials may be considerably ideal as a light absorption layer of a solar cell.

Since CIS thin film and CIGS thin film as light absorption layers are multi-component compounds, manufacturing processes are relatively complicated. A physical method of manufacturing CIS and CIGS thin films includes evaporation and sputtering plus selenization, and a chemical method thereof includes electroplating. In each method, various manufacturing methods may be used according to types of a starting material (metal, binary compound, etc.). A co-evaporation method known to obtain the best efficiency uses four metal elements (copper (Cu), indium (In), gallium (Ga), and Se) as a starting material.

Buffer Layer 40

A p-type semiconductor Cu₂ZnSnS₄ thin film (light absorption layer) in a CZTS solar cell, a p-type semiconductor CuInSe2 thin film or CuInS₂ thin film (light absorption layer) in a CIS solar cell, and a p-type semiconductor Cu(InGa)Se₂ thin film or a Cu(InGa)S₂ thin film (light absorption layer) in a CIGS solar cell form p-n junctions with a n-type semiconductor zinc oxide (ZnO) thin film used as a window layer to be described below.

However, since two materials have large differences in lattice constants and energy bandgaps, the buffer layer 40 having an energy bandgap between those of two materials is required in order to form a good contact. Cadmium sulfide (CdS) may be used as a material for the buffer layer 40 of a solar cell.

Window Layer 50

As described above, the widow layer 50 as an n-type semiconductor forms a p-n junction with a light absorption layer 40 (CZTS layer, CIS layer, or CIGS layer) and functions as a front transparent electrode of a solar cell.

Therefore, the window layer 50 is formed of a material having high optical transmittance and excellent electrical conductivity, such as ZnO. Zinc oxide has an energy bandgap of about 3.3 eV and has a high degree of optical transmission of 80% or more.

Anti-Reflective Layer 60 and Grid Electrode 70

An efficiency of a solar cell may be improved to about 1% when a reflective loss of sunlight incident on the solar cell is reduced. In order to improve the efficiency of the solar cell, the anti-reflective layer 60 is formed on the window layer 50 and magnesium fluoride (MgF2) is generally used as a material for the anti-reflective layer 60 inhibiting the reflection of the sunlight.

The grid electrode 70 acts to collect current on a surface of the solar cell and is formed of aluminum (Al) or nickel/aluminum (Ni/Al). The grid electrode 70 is formed in a patterned area of the anti-reflective layer 60.

When the sunlight is incident on the solar cell having the foregoing configuration, electron-hole pairs are generated between a p-type semiconductor light absorption layer 30 (i.e., a Cu₂ZnSnS₄ thin film in a CZTS solar cell, a CuInSe₂ thin film or a CuInS2 thin film in a CIS solar cell, and a Cu(InGa)Se₂ thin film or a Cu(InGa)S₂ thin film in a CIGS solar cell) and a n-type semiconductor window layer 50. The generated electrons gather at the window layer 60 and the generated holes gather at the light absorption layer 30, and thus, a photovoltage is generated.

In this state, the current flows when an electrical load is connected to the substrate 10 and the grid electrode 70.

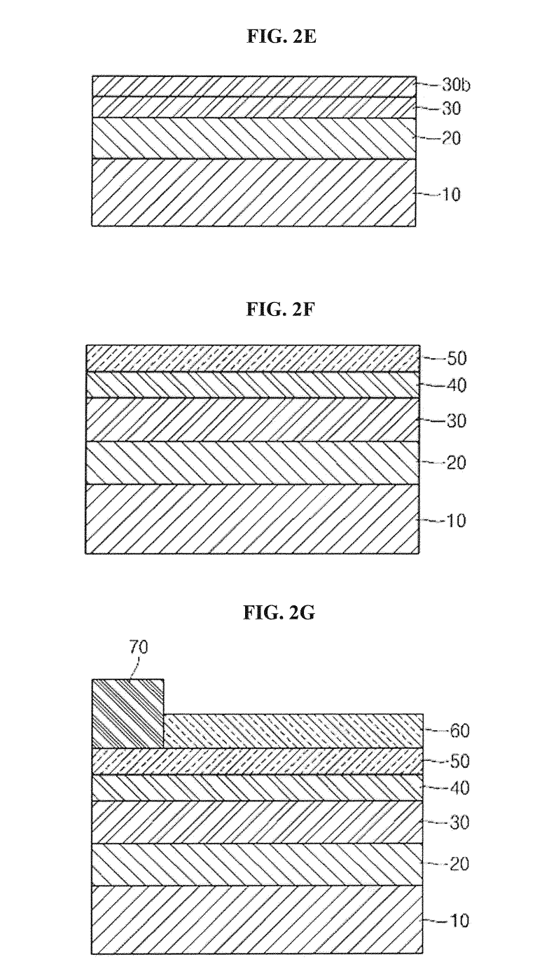

A method of manufacturing a CZTS solar cell, a CIS solar cell, and a CIGS solar cell having the foregoing configuration according to the present invention will be described below with reference to FIG. 1 and FIGS. 2A through 2G.

Referring to FIG. 2A, a substrate 10 is first provided. The substrate 10 may be formed of glass, ceramic, or metal.

As shown in FIG. 2B, a molybdenum thin film 20 is formed on the substrate 10 as a back electrode.

In the method according to the present invention, the back electrode 20 is formed in the following manner.

First, a sputtering process is performed on molybdenum, thereby forming a molybdenum thin film on the glass substrate 10. Thereafter, electron beam is irradiated into the molybdenum thin film, preferably into the entire surface of the molybdenum thin film, thereby finally forming the resultant molybdenum back electrode 20.

When the electron beam is irradiated into the molybdenum thin film, the grain size of the thin film grains may be increased, thereby increasing crystallinity. Consequently, densification of textures (layer structures) of the molybdenum thin film is generated, thereby reducing specific resistivity of the molybdenum thin film.

Meanwhile, the electron beam used in the present invention can efficiently separate electrons/ions using a grid lens and electroplating and can achieve a large area display by separately irradiating electrons and ions through high density plasma (Ar) formation, instead of thermal electrons generated by applying a current to a conventional filament.

Referring to FIG. 2C, a precursor layer 30a for forming a light absorption layer (see 30 in FIG. 1) is formed on the molybdenum thin film 20.

In the process of forming the precursor layer 30a for manufacturing a CZTS solar cell, a stack structure formed of a copper (Cu) layer, a zinc (Zn) layer, a tin (Sn) layer, and a sulfur (S) layer may be formed, or a single layer formed of a compound of copper, zinc, tin, and sulfur may be formed on the molybdenum thin film 20.

Meanwhile, in the process of forming the precursor layer 30a for manufacturing a CIS solar cell, a stack structure formed of a copper layer, an indium layer, and a selenium layer (or a sulfur layer) may be formed, or a single layer formed of a compound of copper, indium, and selenium (or sulfur) may be formed on the molybdenum thin film 20.

Also, in the process of forming the precursor layer 30a for manufacturing a CIGS solar cell, a stack structure formed of a copper layer, an indium layer, a gallium layer, and a selenium layer (or a sulfur layer) may be formed, or a single layer formed of a compound of copper, indium, gallium, and selenium or sulfur may be formed on the molybdenum thin film 20.

The stack structure of elements or a single layer for forming a light absorption layer is formed on the molybdenum thin film 20 and the light absorption precursor layer 30a is then formed by performing a sputtering process or a co-evaporation process.

Referring to FIG. 2D, a diffusion barrier layer 30b is formed on the light absorption precursor layer 30a. The diffusion barrier layer 30b may be formed through a physical vapor deposition (PVD) method or a chemical vapor deposition (CVD) method.

Thereafter, a crystallization operation of the light absorption precursor layer 30a is performed to form a light absorption layer 30.

As described above, the substrate 10 may be formed of glass. Also, sulfur, one of components (Cu—Zn—Sn—S) of the light absorption precursor layer 30a for a CZTS solar cell is a volatile element.

Therefore, in the case that a heat treatment process is performed for the crystallization of the light absorption precursor layer 30a, deformation of the glass substrate 10 may be generated due to heat. Also, sulfur may be volatized in the light absorption precursor layer 30a during the heat treatment process, and thus, a compositional ratio of the components constituting the light absorption precursor layer 30a may be changed.

While the components of the light absorption precursor layer 30a are crystallized through the crystallization operation, the light absorption layer 30 is formed (see FIG. 2E).

Referring to FIG. 2F, the diffusion barrier layer 30b is removed through a dry or wet etching process to expose the light absorption layer 30. A buffered oxide etchant (BOE, wet etching) solution or fluorinated gas (dry etching) may be used in the etching process for removing the diffusion barrier layer 30b.

Thereafter, a buffer layer 40 is formed on the light absorption layer 30 and a window layer 50 is formed on the buffer layer 40.

As described above, since the light absorption layer 30 and the window layer 50 have a large difference in their energy bandgaps, a good p-n junction may be difficult to be formed. Therefore, the buffer layer 40 formed of a material having a bandgap between those of the light absorption layer 30 and the window layer 50 (e.g., cadmium sulfide having an energy bandgap of 2.46 eV) may be formed between the light absorption layer 30 and the window layer 50.

The window layer 50 as an n-type semiconductor forms a p-n junction with the light absorption layer 30 and functions as a front transparent electrode of a solar cell. Therefore, the window layer 50 may be formed of a material having high optical transmittance and excellent electrical conductivity, e.g., zinc oxide (ZnO). Zinc oxide has an energy bandgap of about 3.3 eV and has a degree of optical transmission of 80% or more.

Referring to FIG. 2G, an anti-reflective layer 60 is formed on the window layer 50 through a specific process, for example, a sputtering process and some area of the anti-reflective layer 60 is patterned, and a grid electrode 70 as an upper electrode is then formed in the patterned area.

Magnesium fluoride (MgF2) is used as a material for the anti-reflective layer 60 decreasing a reflective loss of the sunlight incident on the solar cell. The grid electrode 70 collecting current on a surface of the solar cell is formed of aluminum (Al) or nickel/aluminum (Ni/Al).

Hereinafter, the process of forming a molybdenum thin film (back electrode) using electron beam irradiation will be described in detail.

A molybdenum thin film having a predetermined thickness was formed by depositing molybdenum on a glass substrate just by using a general process, that is, a DC sputtering process. Conditions of the processing chamber in the molybdenum depositing process are as follows:

Pressure: 7×10E⁻⁷ torr

Flow rate of argon (Ar) gas: 20 sccm

Temperature: Room temperature

Deposition thickness: 250 nm

Rotation speed of substrate: 5 RPM

Thin films were formed by depositing molybdenum in the processing chamber maintained in the atmosphere stated above with operating pressures of 10 mtorr (Comparative Example 1), 5 mtorr (Comparative Example 2), 3 mtorr (Comparative Example 3) and 1 mtorr (Comparative Example 4).

Specific resistivity of each of the thus formed molybdenum thin films according to the respective Comparative Examples was measured, and the results thereof are listed in Table 1.

TABLE 1

| | Comparative | Comparative | Comparative | Comparative |
|---|---|---|---|---|
| | Example 1 | Example 2 | Example 3 | Example 4 |
| Operating | 10 mtorr | 5 mtorr | 3 mtorr | 1 mtorr |
| pressure | | | | |
| Specific | 9.2E−04 | 5.5E−04 | 2.9E−04 | 5.4E−05 |
| resistivity | Ω · cm | Ω · cm | Ω · cm | Ω · cm |

In order to form molybdenum thin films formed according to the present invention, the following process was performed.

First, molybdenum thin films each having a predetermined thickness were formed on the glass substrate using a DC sputtering process.

Conditions of the processing chamber in the molybdenum depositing process are as follows:

Pressure: 7×10E⁻⁷ torr

Flow rate of argon (Ar) gas: 7 sccm

Temperature: Room temperature

Deposition time: 5 minutes

Rotation speed of substrate: 5 RPM

Thin films were formed by depositing molybdenum in the processing chamber maintained in the atmosphere stated above with operating pressures of 10 mtorr (Example 1), 5 mtorr (Example 2), 3 mtorr (Example 3) and 1 mtorr (Example 4).

Thereafter, electron beam irradiation was performed on the molybdenum thin films formed in the respective Examples for 5 minutes. Here, the electron beam was irradiated under the following conditions:

DC power: 3.0 kv

RF power: 300 W

Here, in order to make the molybdenum thin films have uniform specific resistivity, electron beams were irradiated into the entire surface of each of the molybdenum thin films.

After the electron beam irradiation was performed, specific resistivity of each of the thus formed molybdenum thin films according to the respective Examples was measured, and the results thereof are listed in Table 2.

TABLE 2

| | Example 1 | Example 2 | Example 3 | Example 4 |
|---|---|---|---|---|
| Operating | 10 mtorr | 5 mtorr | 3 mtorr | 1 mtorr |
| pressure | | | | |
| Specific | 6.5E−04 | 2.2E−04 | 8.0E−05 | 3.5E−05 |
| resistivity | Ω · cm | Ω · cm | Ω · cm | Ω · cm |

As confirmed from the table above, the specific resistivity of each of the thus formed molybdenum thin films according to Examples 1 to 4 measured after performing the electron beam irradiation was noticeably reduced, compared to the specific resistivity of each of the thus formed molybdenum thin films according to Comparative Examples 1 to 4 in which the electron beam irradiation was not performed.

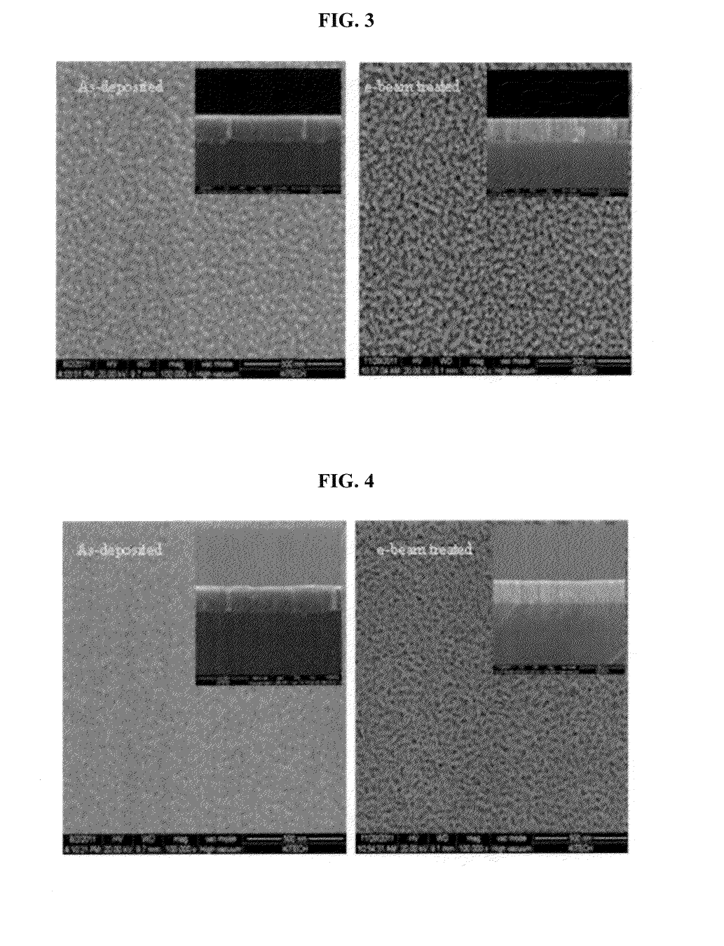

FIG. 3 illustrates photographs showing molybdenum thin films formed according to Comparative Example 1 and Example 1, in which the left photograph shows the molybdenum thin film formed according to Comparative Example 1 and the right photograph shows the molybdenum thin film formed according to Example 1, respectively.

FIG. 4 illustrates photographs showing molybdenum thin films formed according to Comparative Example 2 and Example 2, in which the left photograph shows the molybdenum thin film formed according to Comparative Example 2 and the right photograph shows the molybdenum thin film formed according to Example 2, respectively.

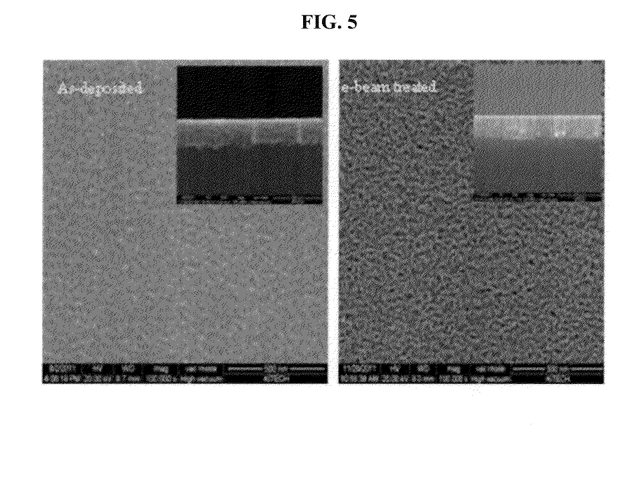

FIG. 5 illustrates photographs showing molybdenum thin films formed according to Comparative Example 3 and Example 3, in which the left photograph shows the molybdenum thin film formed according to Comparative Example 3 and the right photograph shows the molybdenum thin film formed according to Example 3, respectively.

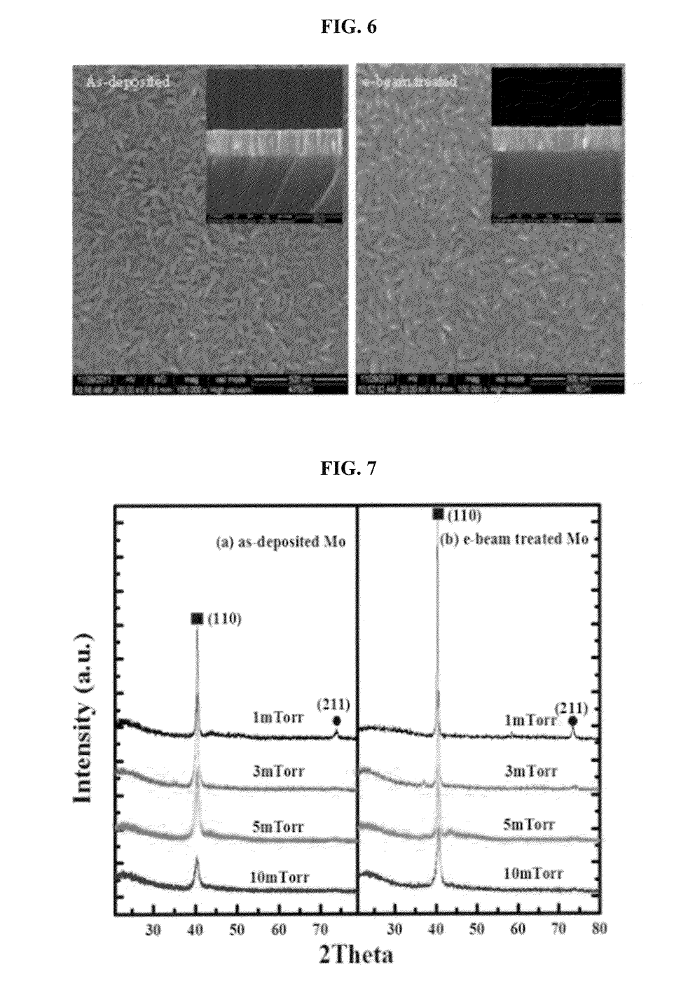

FIG. 6 illustrates photographs showing molybdenum thin films formed according to Comparative Example 4 and Example 4, in which the left photograph shows the molybdenum thin film formed according to Comparative Example 4 and the right photograph shows the molybdenum thin film formed according to Example 4, respectively.

As confirmed from the photographs, compared to the molybdenum thin films according to Comparative Examples 1, 2, 3 and 4, the molybdenum thin films according to Examples 1, 2, 3 and 4 have less dense textures. Therefore, the molybdenum thin films according to Examples 1, 2, 3 and 4 have smaller resistivity values than the molybdenum thin films according to Comparative Examples 1, 2, 3 and 4.

FIG. 7 is a graph comparing resistivity measuring results of molybdenum thin films formed according to Comparative Examples 1 to 4 and Examples 1 to 4, in which the left graph shows resistivity measuring results of the molybdenum thin films formed according to Comparative Examples 1 to 4 and the right graph shows resistivity measuring results of the molybdenum thin films formed according to Examples 1 to 4.

From the results shown in tables and graphs stated above, it could be understood that the resistivity values of the molybdenum thin films formed according to Examples 1 to 4 were noticeably reduced, compared to those of the molybdenum thin films formed according to Comparative Examples 1 to 4.

Although exemplary embodiments of the present invention have been described in detail hereinabove, it should be understood that many variations and modifications of the basic inventive concept herein described, which may appear to those skilled in the art, will still fall within the spirit and scope of the exemplary embodiments of the present invention as defined by the appended claims.

1. A method for manufacturing a solar cell comprising:
forming a molybdenum thin film on a substrate; and
performing a post-processing process on the molybdenum thin film to form a back electrode,
wherein the post-processing process with respect to the molybdenum thin film is performed by irradiating an electron beam.

2. The method of claim 1, wherein the electron beam is irradiated into the entire surface of the back electrode.

3. The method of claim 1, wherein the electron beam post-processing process is performed in a processing chamber maintained in an argon gas atmosphere of 7×10E⁻⁷ torr in pressure and 5 to 10 sccm in flow rate using the electron beam having DC power of 2.5 to 3.5 Kv and RF power of 200 to 300 W.

4. The method of claim 3, wherein a processing time of the electron beam is 5 minutes or less.

5. A method for manufacturing a solar cell comprising:
forming a substrate;
sputtering a molybdenum on the substrate to form a molybdenum thin film on the substrate; and
irradiating an electron beam on the molybdenum thin film layer thereby forming a back electrode.

6. The method of claim 5, wherein the substrate is formed of glass.

7. The method of claim 5, wherein the electron beam is irradiated into the entire surface of the molybdenum thin film.

8. The method of claim 5, wherein the irradiation is performed in a processing chamber maintained in an argon gas atmosphere of 7×10E⁻⁷ torr in pressure and 5 to 10 sccm in flow rate using the electron beam having DC power of 2.5 to 3.5 Kv and RF power of 200 to 300 W.

9. The method of claim 8, wherein a processing time of the electron beam irradiating is 5 minutes or less.

10. The method of claim 5, wherein the irradiating is performed using a grid lens and electroplating through high density plasma (Ar) formation.
